(19) United States
(12) Patent Application Publication
(10) Pub. No.: US 2002/0125494 A1
(43) Pub. Date: Sep. 12, 2002

(54) Semiconductor light emitting device and method of producing the same

(76) Inventor: Shinji Isokawa, Kyoto (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/059,243

(22) Filed: Jan. 31, 2002

(30) Foreign Application Priority Data
Feb. 2, 2001 (JP) 2001-27244

(51) Int. Cl. H01L 21/00; H01L 33/00

(52) U.S. Cl. 257/99; 257/100; 438/22; 438/25; 438/27; 257/98

(57) ABSTRACT

A semiconductor light emitting device including a lead terminal having an element mount section, a semiconductor light emitting chip mounted on the element mount section, and a first resin formed by molding so as to cover the semiconductor light emitting chip and the element mount section. A second resin may be additionally provided so as to cover the outside of the first resin. The first resin includes a resin material with a fluorescent substance dispersed therein.

### BACKGROUND OF THE INVENTION

1. Field of the Invention

The present invention relates to a semiconductor light emitting device, and particularly to a semiconductor light emitting device by which, for example, white emission color can be obtained, and a method of producing the same.

2. Description of Related Art

Semiconductor light emitting devices, including a light emitting diode as a typical one, have advantages of compactness and long life, and have been conventionally used in wide range, for example, for display lamps of various kinds of apparatus. In recent days, as blue emitting diodes are put to practical use, semiconductor light emitting devices come into wider use. For example, there are semiconductor light emitting devices capable of obtaining a white emission color by combining a blue light emitting diode and a fluorescent substance. These are used for illuminators, displays or the like.

FIG. 2 is a schematic sectional view showing a structure of a conventional light emitting device capable of obtaining a white emission color. A pair of lead terminals 31, 32 are disposed in parallel. At the upper end of one lead terminal 31, an element mount section 33 in the form of an upwardly opened recess is provided. The bottom of the recess of the element mount section 33 is a flat surface 33a, on which a light emitting diode chip 35 is die-bonded by an electrically conductive paste 34.

The light emitting diode chip 35 includes a GaN compound semiconductor layer and has blue emission color. Inside the recess of the element mount section 33, a fluorescent layer 36 is provided around the light emitting diode chip 35. The fluorescent layer 36 includes a fluorescent substance, which emits, for example, yellow fluorescent light when receiving blue light emitted from the light emitting chip 35. A bonding wire 37 connects the upper surface of the light emitting diode chip 35 and the upper end of the other lead terminal 32 with each other. The light emitting diode chip 35, the element mount section 33, the bonding wire 37 and parts of the lead terminals 31, 32 respectively are covered with a transparent resin 38 having visible-light permeability.

When energization between the lead terminals 31, 32 is effected, the light emitting diode chip 35 emits blue light. The fluorescent layer 36 receives this blue light and emits fluorescent light. When the fluorescent layer 36 has a suitable amount (that is, a suitable thickness), the blue light and the fluorescent light are properly mixed to obtain white light having a high degree of whiteness. When the fluorescent layer 36 has an excessive amount (that is, an excessive thickness), the blue light passing through the fluorescent layer 36 is weakened and becomes, as a whole, a color near a fluorescent color (for example, yellow). On the other hand, when the fluorescent layer 36 has an excessively small amount (that is, an excessively small thickness), the blue light passing through the fluorescent layer 36 is excessively strong and becomes, as a whole, a pale color. Since the transparent resin 38 has permeability with respect to these lights, these mixed color lights can be observed from outside.

In the process of producing such a semiconductor light emitting device, the light emitting diode chip 35 is die-bonded on the flat surface 33a and the bonding wire 37 is connected to the light emitting diode chip 35. Thereafter, the fluorescent layer 36 is disposed around the light emitting diode chip 35 by a dipping method, dispenser method or the like. That is, the light emitting diode chip 35 is dipped in a paste having the fluorescent substance blended therein, or such a paste is provided around the light emitting diode chip 35 through a dispenser in the form of an injector needle. Then, treatments such as drying and hardening are carried out, so that the fluorescent layer 36 is obtained. By these methods, the fluorescent layer 36 is provided only in a limited region around the light emitting diode chip 35.

However, in the dipping method, the amount of the paste attached to the light emitting diode chip 35 is not strictly controlled. Besides, the amount of the paste provided according to a dispenser method is not always fixed. As a result, the amount (thickness) of the fluorescent layer 36 formed around the light emitting diode chip 35 is not fixed.

Further, since the paste used in the dipping method, dispenser method and the like has a low viscosity, the fluorescent substance is apt to precipitate and separate in the paste.

Consequently, the fluorescent layer 36 formed using such a paste sometimes has uneven thickness, unfixed fluorescent substance content or nonuniform fluorescent substance distribution. As a result, the color of light emitted from the semiconductor light emitting device is not always white, but sometimes becomes pale or yellowish color. Therefore, the production yield becomes low.

### SUMMARY OF THE INVENTION

An object of the present invention is to provide a semiconductor light emitting device by which desired color light can be obtained, and a method of producing the same.

Another object of the present invention is to provide a semiconductor light emitting device capable of obtaining a high production yield, and a method of producing the same.

A semiconductor light emitting device according to the present invention includes a lead terminal having an element mount section, a semiconductor light emitting chip mounted on the element mount section, and a first resin formed by molding a resin material with a fluorescent substance dispersed therein so as to cover the semiconductor light emitting chip and the element mount section. A second resin covering the outside of the first resin may be provided in addition.

The semiconductor light emitting chip may be connected to a pair of lead terminals. For example, the semiconductor light emitting chip may be die-bonded on the element mount section provided at the top end of one lead terminal, with the other lead terminal and the semiconductor light emitting chip being connected to each other by a bonding wire.

According to the present invention, since the fluorescent substance is dispersed in the first resin, it is distributed around the semiconductor light emitting chip. Therefore, for example, if the emission color of the semiconductor light emitting chip is blue and the fluorescent substance emits yellow color on receiving this blue light, light of a mixed color of blue light and yellow light can be obtained.

Further, the first resin is formed by molding. That is, the first resin is formed by injecting the resin into a space having a fixed capacity such as a cavity of a mold. The region in which the first resin is formed can be a region, for example, including the semiconductor light emitting chip, the element mount section, the bonding wire and a part of the lead terminal.

For example, when a transfer molding method is carried out, a part of the lead terminal is disposed in such a manner that the die-bonded and wire-bonded semiconductor light emitting chip, the element mount section and the bonding wire are included in a cavity having a fixed capacity. Then, the first resin in the fluid state is injected into the cavity. Thereby the first resin is formed around the semiconductor light emitting chip. Since the amount of the first resin is determined by the capacity of the cavity, good reproducibility can be obtained.

Further, the resin used in the transfer molding method has a high viscosity even if it is in the fluid state, so that the resin and the fluorescent substance are hard to separate from each other. Consequently, the first resin can be kept homogeneous and the fluorescent substance content thereof can be kept at a predetermined value.

As apparent from the above description, a predetermined amount of the first resin having a fixed fluorescent substance content and homogeneity is formed around the semiconductor light emitting chip. If the semiconductor light emitting chip is positioned substantially in the center of the first resin, the thickness of the first resin around the semiconductor light emitting chip is substantially fixed. Therefore, in such a semiconductor light emitting device, the emission color (e.g. blue) of the semiconductor light emitting chip and the emission color (e.g. yellow) of the fluorescent substance are mixed in a predetermined ratio, so that a desired color (e.g. white having a high degree of whiteness) light can be obtained. Further, when a number of such semiconductor light emitting devices are produced, the color (e.g. white having a high degree of whiteness) of light emitted from each semiconductor light emitting device has a high reproducibility. That is, this semiconductor light emitting device has a high production yield.

The foregoing and other objects, features, aspects and advantages of the present invention will become more apparent from the following detailed description of embodiments of the present invention given with the accompanying drawings.

### BRIEF DESCRIPTION OF THE DRAWINGS

FIGS. 1(a) and 1(b) are schematic sectional views showing, in the order of the producing process, an embodiment of a method of producing a semiconductor light emitting device capable of obtaining a white emission color according to the present invention.

FIG. 2 is a schematic sectional view of a conventional semiconductor light emitting device capable of obtaining white emission color.

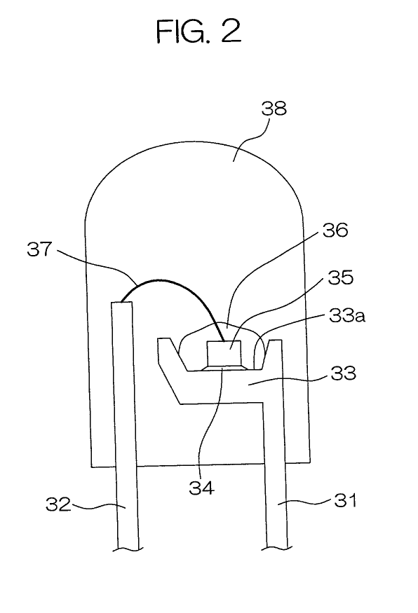

### DESCRIPTION OF THE PREFERRED EMBODIMENTS

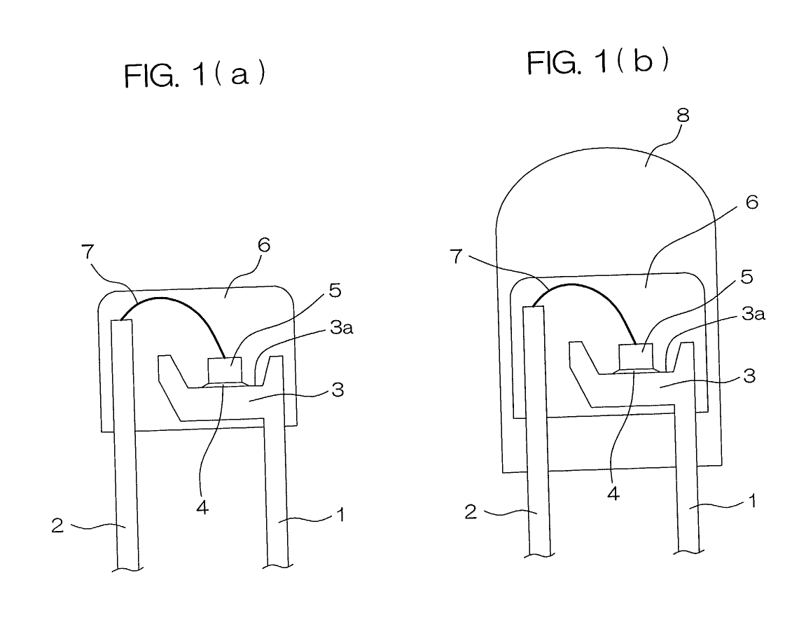

FIGS. 1(a) and 1(b) are schematic sectional views showing, in the order of the producing process, an embodiment of a method for producing a semiconductor light emitting device capable of obtaining a white emission color according to the present invention.

A pair of lead terminals 1, 2 are disposed in parallel. At the upper end of one lead terminal 1, an element mount section 3 in the form of an upwardly opened recess is provided. The bottom of the recess of the element mount section 3 is a flat surface 3a, on which a light emitting diode chip 5 is die-bonded by an electrically conductive paste 4. The light emitting diode chip 5 includes a GaN compound semiconductor layer and has blue emission color. A bonding wire 7 connects the upper surface of the light emitting diode chip 5 and the upper end of the other lead terminal 2 with each other.

A first resin 6, molded in a substantially cylindrical shape, is disposed in a region including the light emitting diode chip 5, the element mount section 3, the bonding wire 7 and a part of the lead terminal 2. The first resin 6 is formed by uniformly blending, into a sealing resin, a fluorescent substance which emits, for example, yellow fluorescent light on receiving blue light emitted from the light emitting diode chip 5. The light emitting diode chip 5 is positioned substantially at the center of the first resin 6, and the first resin 6 formed around the light emitting diode chip 5 has substantially equal thickness in all directions.

The outside of the first resin 6 is further covered with a second resin 8. The second resin 8 has visible-light permeability.

When energization between the lead terminals 1, 2 is effected, the light emitting diode chip 5 emits blue light. The fluorescent substance in the first resin 6 receives the blue light and emits yellow fluorescent light. These lights pass through the second resin 8, and therefore, mixed color light of the blue light and the yellow light can be observed from outside.

The first resin 6 is formed in a relatively large region including the light emitting diode chip 5, the element mount section 3, the bonding wire 7 and a part of the lead terminal 2. Accordingly, the first resin 6 can be molded by injecting the resin in a space having a predetermined capacity such as a cavity of a mold. For example, in the transfer molding method, parts of the lead terminals 1, 2 respectively are disposed in such a manner that the die-bonded and wire-bonded light emitting diode chip 5, the element mount section 3 and the bonding wire 7 can be included in a cavity having a predetermined capacity. Then, the first resin 6 in the fluid state is injected into the cavity. Thereby, the first resin 6 is formed around the light emitting diode chip 5 (FIG. 1(a)). Since the amount of the first resin 6 is determined by the capacity of the cavity, good reproducibility can be obtained.

A semiconductor light emitting device according to the present invention (FIG. 1(b)) can be obtained by similarly molding, by the transfer molding method, the second resin 8 on the outside of the first resin 6 molded as abovementioned (FIG. 1(a)).

Further, a resin used in the transfer molding method has a high viscosity even if it is in the fluid state. Therefore, the sealing resin and the fluorescent substance are hard to separate from each other, so that the first resin 6 can be kept homogeneous and the fluorescent substance content thereof can be kept at a predetermined value.

As apparent from the abovementioned, a predetermined amount of the first resin 6 including fluorescent substance uniformly and in a fixed content is disposed around the light emitting diode chip 5. Consequently, in such a semiconductor light emitting device, since blue light emitted from the light emitting diode chip 5 and yellow light emitted from the fluorescent substance are mixed in a predetermined ratio, a desired color, for example, white light having a high degree of whiteness can be obtained. Further, when a number of such semiconductor light emitting devices are produced, the color (for example, white having a high degree of whiteness) of light emitted from each semiconductor light emitting device has a high reproducibility. That is, the semiconductor light emitting device has a high production yield.

The first resin 6 may be formed in a region in which the lead terminal 2 is not included.

Although an embodiment of the present invention has been described and illustrated in detail, it is clearly understood that the same is by way of illustration and example only and is not to be taken by way of limitation, the spirit and scope of the present invention being limited only by the terms of the appended claims.

This application corresponds to the Japanese Patent Application No. 2001-27244 filed in the Japanese Patent Office on Feb. 2, 2001, and the whole disclosures of the Japanese application are incorporated herein by reference.

What is claimed is:

1. A semiconductor light emitting device comprising:
a lead terminal having an element mount section;
a semiconductor light emitting chip mounted on the element mount section; and
a first resin formed by molding a resin material with a fluorescent substance dispersed therein so as to cover the semiconductor light emitting chip and the element mount section.

2. A semiconductor light emitting device as claimed in claim 1, further comprising a second resin covering an outside of the first resin.

3. A semiconductor light emitting device as claimed in claim 1, in which the semiconductor light emitting device is disposed substantially in a center of the first resin.

4. A semiconductor light emitting device as claimed in claim 1, further comprising another lead terminal connected to the semiconductor light emitting chip by a bonding wire, in which
the first resin is formed so as to cover a part of said another lead terminal.

5. A semiconductor light emitting device as claimed in claim 1, in which the first resin is formed in a cylindrical shape.

6. A semiconductor light emitting device as claimed in claim 1, in which an emission color of the semiconductor light emitting chip is blue and the fluorescent substance emits yellow fluorescent light.

7. A method of producing a semiconductor light emitting device comprising steps of:
mounting a semiconductor light emitting chip on an element mount section of a lead terminal; and
forming a first resin by molding a resin material with a fluorescent substance dispersed therein so as to cover the semiconductor light emitting chip and the element mount section.

8. A method of producing a semiconductor light emitting device as claimed in claim 7, further comprising a step of forming a second resin by molding so as to cover an outside of the first resin.

9. A method of producing a semiconductor light emitting device as claimed in claim 7, in which the first resin is molded by a transfer molding method.

10. A method of producing a semiconductor light emitting device as claimed in claim 7, in which the first resin is molded in such a manner that the semiconductor light emitting chip is positioned substantially in a center of the first resin.

11. A method of producing a semiconductor light emitting device as claimed in claim 7, further comprising a step of electrically connecting the semiconductor light emitting chip to another lead terminal by a bonding wire, in which
the first resin is molded so as to cover the bonding wire and a part of said another lead terminal.
